(19) United States
(12) Patent Application Publication
(10) Pub. No.: US 2014/0235033 A1
(43) Pub. Date: Aug. 21, 2014

(54) NON-CONVENTIONAL METHOD OF SILICON WAFER SAWING USING A PLURALITY OF WAFER SAW ROTATIONAL ANGLES

(71) Applicant: MICROCHIP TECHNOLOGY INCORPORATED, Chandler, AZ (US)

(72) Inventors: Matthew Bunker, Chandler, AZ (US); Ekgachai Kenganantanon, Chacherngsao (TH); Surapol Sawatjeen, Chacherngsao (TH)

(73) Assignee: MICROCHIP TECHNOLOGY INCORPORATED, Chandler, AZ (US)

(21) Appl. No.: 13/769,651

(22) Filed: Feb. 18, 2013

(51) Int. Cl. H01L 21/78

(52) U.S. Cl. CPC H01L 21/78
USPC 438/460

(57) ABSTRACT

A silicon wafer saw can be set to either three or four different cutting angle orientations from a zero degree reference to produce integrated circuit dice having corners greater than 90 degrees. Three different saw angle orientations will produce six sided dice, and four different saw cutting angle orientations will produce eight sided dice.

### TECHNICAL FIELD

The present disclosure relates to methods of sawing a silicon wafer for separating a plurality of dice therein, and in particular, to sawing the silicon wafer so that each die corner has an angle that is greater than 90 degrees.

### BACKGROUND

Silicon wafer sawing is the process of cutting the wafer so that a plurality of integrated circuit dice are separated therefrom. Scribe lines or saw streets are areas between the dice where the saw passes through to separate the plurality of dice. Currently, sawing of the wafer is performed at zero (0) degrees and 90 degrees, resulting in either square or rectangular dice having four sides and 90 degree corners. However some applications require dice having corners with angles greater than 90 degrees.

### SUMMARY

Therefore there is need for a way to separate a plurality of dice from a silicon wafer so that the separated dice have corners with angles greater than 90 degrees.

According to an embodiment, a method for separating a plurality of integrated circuit dice from a silicon wafer may comprise the steps of: setting a wafer cutting tool to a first cutting angle, wherein the first cutting angle may be at substantially 90 degrees from a zero degree reference; cutting the silicon wafer with the wafer cutting tool at the first cutting angle; setting the wafer cutting tool to a second cutting angle, wherein the second cutting angle may be less than 90 degrees from the zero degree reference; cutting the silicon wafer with the wafer cutting tool at the second cutting angle; setting the wafer cutting tool to a third cutting angle, wherein the third cutting angle may be greater than 90 degrees from the zero degree reference; and cutting the silicon wafer with the wafer cutting tool at the third cutting angle; wherein a plurality of integrated circuit dice may be separated from the silicon wafer and each one of the plurality of integrated circuit dice have six sides with corners greater than 90 degrees.

According to a further embodiment of the method, the silicon wafer may be mounted to a wafer mount with mounting tape for holding the silicon wafer during cutting thereof with the wafer cutting tool. According to a further embodiment of the method, passivation of each of the plurality of integrated circuit dice remains sealed after the steps of cutting the silicon wafer.

According to a further embodiment of the method, the step of cutting the silicon wafer at the first cutting angle comprises the steps of: cutting a first side of each of the plurality of integrated circuit dice at the first cutting angle; and cutting a second side of each of the plurality of integrated circuit dice at the first cutting angle. According to a further embodiment of the method, the step of cutting the silicon wafer at the second cutting angle comprises the steps of: cutting a third side of each of the plurality of integrated circuit dice at the second cutting angle; and cutting a fourth side of each of the plurality of integrated circuit dice at the second cutting angle. According to a further embodiment of the method, the step of cutting the silicon wafer at the third cutting angle comprises the steps of: cutting a fifth side of each of the plurality of integrated circuit dice at the third cutting angle; and cutting a sixth side of each of the plurality of integrated circuit dice at the third cutting angle.

According to another embodiment, a method for separating a plurality of integrated circuit dice from a silicon wafer may comprise the steps of: setting a wafer cutting tool to a first cutting angle, wherein the first cutting angle may be at substantially 90 degrees from a zero degree reference; cutting the silicon wafer with the wafer cutting tool at the first cutting angle; setting the wafer cutting tool to a second cutting angle, wherein the second cutting angle may be less than 90 degrees from the zero degree reference; cutting the silicon wafer with the wafer cutting tool at the second cutting angle; setting the wafer cutting tool to a third cutting angle, wherein the third cutting angle may be greater than 90 degrees from the zero degree reference; cutting the silicon wafer with the wafer cutting tool at the third cutting angle; setting the wafer cutting tool to a fourth cutting angle, wherein the fourth cutting angle may be at substantially the zero degree reference; and cutting the silicon wafer with the wafer cutting tool at the fourth cutting angle; wherein a plurality of integrated circuit dice may be separated from the silicon wafer and each one of the plurality of integrated circuit dice have eight sides with corners greater than 90 degrees.

According to a further embodiment of the method, the silicon wafer may be mounted to a wafer mount with mounting tape for holding the silicon wafer during cutting thereof with the wafer cutting tool. According to a further embodiment of the method, passivation of each of the plurality of integrated circuit dice remains sealed after the steps of cutting the silicon wafer.

According to a further embodiment of the method, the step of cutting the silicon wafer at the first cutting angle comprises the steps of: cutting a first side of each of the plurality of integrated circuit dice at the first cutting angle; and cutting a second side of each of the plurality of integrated circuit dice at the first cutting angle. According to a further embodiment of the method, the step of cutting the silicon wafer at the second cutting angle comprises the steps of: cutting a third side of each of the plurality of integrated circuit dice at the second cutting angle; and cutting a fourth side of each of the plurality of integrated circuit dice at the second cutting angle.

According to a further embodiment of the method, the step of cutting the silicon wafer at the third cutting angle comprises the steps of: cutting a fifth side of each of the plurality of integrated circuit dice at the third cutting angle; and cutting a sixth side of each of the plurality of integrated circuit dice at the third cutting angle. According to a further embodiment of the method, the step of cutting the silicon wafer at the fourth cutting angle comprises the steps of: cutting a seventh side of each of the plurality of integrated circuit dice at the fourth cutting angle; and cutting an eighth side of each of the plurality of integrated circuit dice at the fourth cutting angle.

### BRIEF DESCRIPTION OF THE DRAWINGS

A more complete understanding of the present disclosure may be acquired by referring to the following description taken in conjunction with the accompanying drawings wherein:

FIG. 1 illustrates a schematic process flow diagram of a silicon wafer being separated into a plurality of integrated circuit dice;

FIG. 2 illustrates a schematic plan view of a wafer cutting operation producing a plurality of integrated circuit dice having four sides with 90 degree corners;

FIG. 3 illustrates a schematic plan view of a wafer cutting operation producing a plurality of integrated circuit dice having six sides with corners of greater than 90 degrees, according to a specific example embodiment of this disclosure; and

FIG. 4 illustrates a schematic plan view of a wafer cutting operation producing a plurality of integrated circuit dice having eight sides with corners of greater than 90 degrees, according to another specific example embodiment of this disclosure.

While the present disclosure is susceptible to various modifications and alternative forms, specific example embodiments thereof have been shown in the drawings and are herein described in detail. It should be understood, however, that the description herein of specific example embodiments is not intended to limit the disclosure to the particular forms disclosed herein, but on the contrary, this disclosure is to cover all modifications and equivalents as defined by the appended claims.

### DETAILED DESCRIPTION

Cutting dice from a silicon wafer in way that eliminates sharp 90 degree corners on the dice is desired in certain integrated circuit fabrication and packaging applications. However, when deviating from the traditional square and rectangular dice having 90 degree corners, care must be taken not to break the passivation seal of the desired die. Also it is desirable to maximize the yield of dice having greater than 90 degree corners using existing die/wafer topologies.

Referring now to the drawing, the details of specific example embodiments are schematically illustrated. Like elements in the drawings will be represented by like numbers, and similar elements will be represented by like numbers with a different lower case letter suffix.

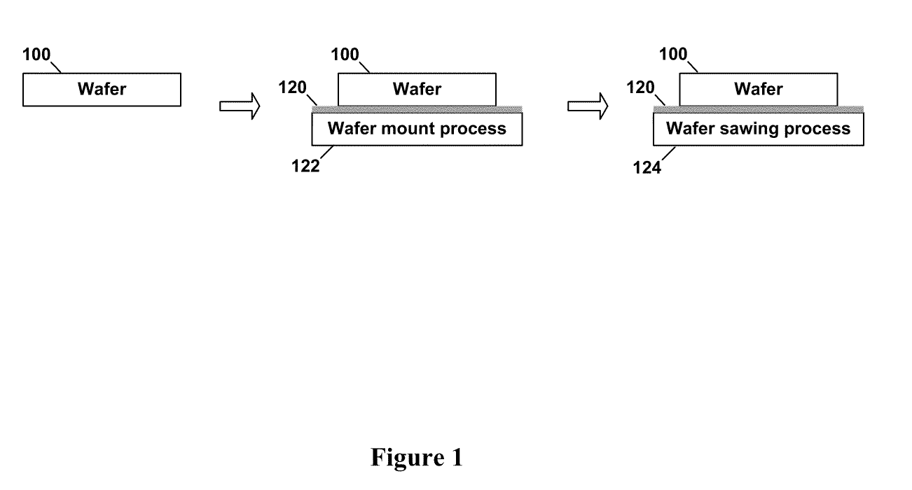

Referring to FIG. 1, depicted is a schematic process flow diagram of a silicon wafer being separated into a plurality of integrated circuit dice. A silicon wafer 100 is mounted (122) on a mounting tape 120 that adheres to the back of the wafer 100. The mounting tape 120 provides support for wafer handling during the wafer sawing process 124. The wafer sawing process 124 is used to cut the wafer so that individual integrated circuit dice are separated therefrom.

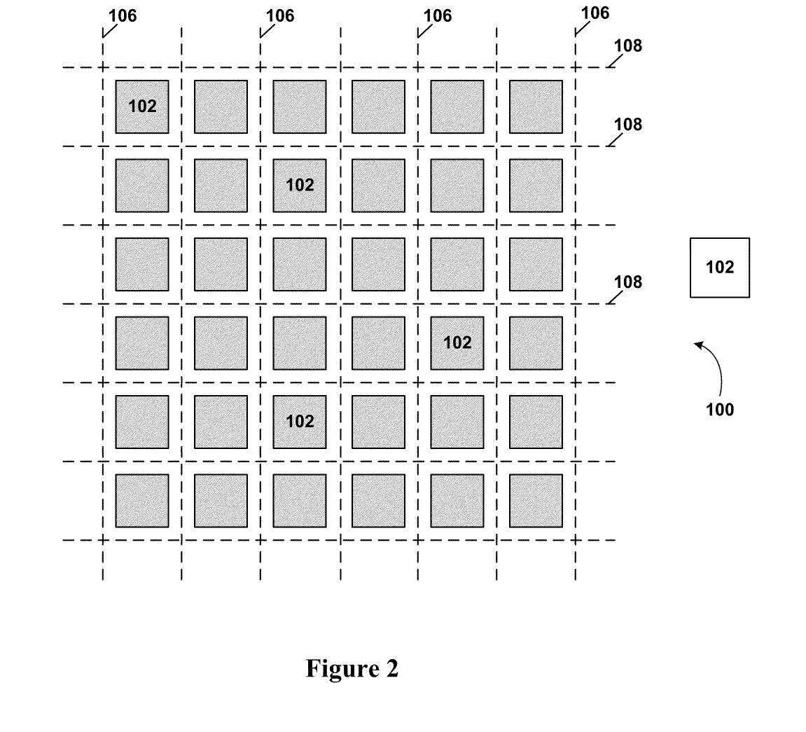

Referring to FIG. 2, depicted is a schematic plan view of a wafer cutting operation producing a plurality of integrated circuit dice having 90 degree corners. “Scribe lines” or “saw streets” 106 and 108 are areas between the integrated circuit dice 102 where a dicing saw (not shown) may pass (cut) through the wafer 100, thereby separating the plurality of dice 102 from the wafer 100. Scribe line 108 is oriented at 0 degrees and scribe line 106 is oriented at 90 degrees. Each of the plurality of dice 120 will be square or rectangular and have four sides with 90 degree corners.

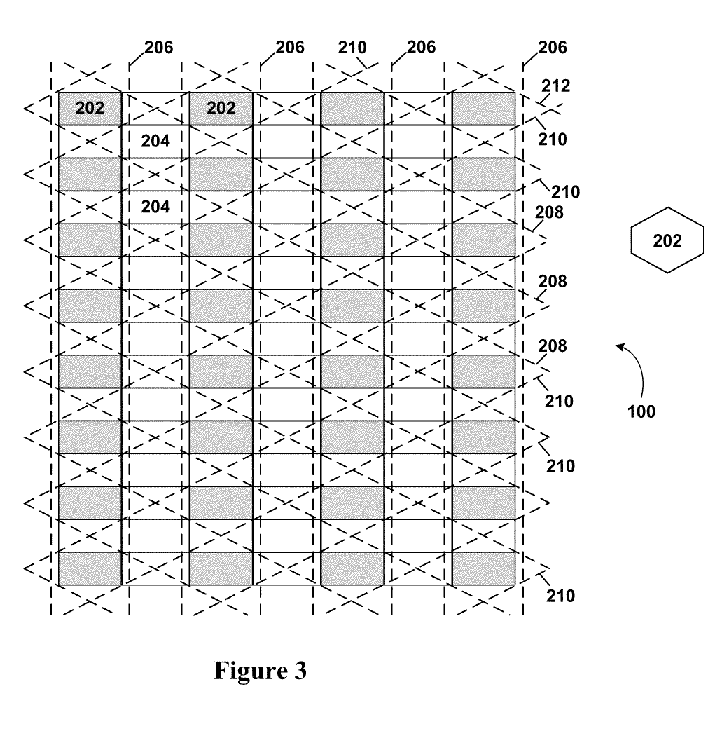

Referring to FIG. 3, depicted is a schematic plan view of a wafer cutting operation producing a plurality of integrated circuit dice having six sides with corners greater than 90 degrees, according to a specific example embodiment of this disclosure. A plurality of integrated circuit dice 202 are separated (cut) from the silicon wafer 100. Each of the dice 202 are six sided and have corners with angles of greater than 90 degrees. There are three different angle scribe lines 206, 210 and 212. The scribe lines 206 are at approximately 90 degrees to a zero degree reference. Scribe lines 210 are less than 90 degrees to the zero degree reference. And scribe lines 212 are greater than 90 degrees to the zero degree reference. Therefore the wafer cutting saw (not shown) need be set to only three different cutting angles. Die areas 204 are sacrificial areas for the wafer cutting saw (not shown) to pass through.

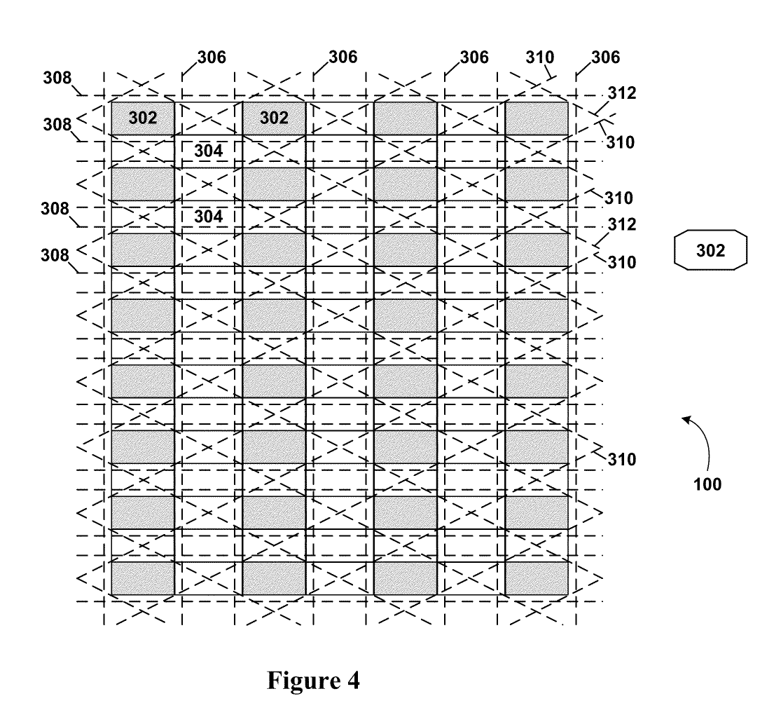

Referring to FIG. 4, depicted is a schematic plan view of a wafer cutting operation producing a plurality of integrated circuit dice having eight sides with corners greater than 90 degrees, according to another specific example embodiment of this disclosure. A plurality of integrated circuit dice 302 are separated (cut) from the silicon wafer 100. Each of the dice 302 are eight sided and have corners with angles of greater than 90 degrees. There are four different angle scribe lines 306, 308, 310 and 312. The scribe lines 306 are at approximately 90 degrees to a zero degree reference. The scribe lines 308 are at approximately 0 degrees to the zero degree reference. Scribe lines 310 are less than 90 degrees to the zero degree reference. And scribe lines 312 are greater than 90 degrees to the zero degree reference. Therefore the wafer cutting saw (not shown) need be set to only four different cutting angles. Die areas 304 are sacrificial areas for the wafer cutting saw (not shown) to pass through.

While embodiments of this disclosure have been depicted, described, and are defined by reference to example embodiments of the disclosure, such references do not imply a limitation on the disclosure, and no such limitation is to be inferred. The subject matter disclosed is capable of considerable modification, alteration, and equivalents in form and function, as will occur to those ordinarily skilled in the pertinent art and having the benefit of this disclosure. The depicted and described embodiments of this disclosure are examples only, and are not exhaustive of the scope of the disclosure.

1. A method for separating a plurality of integrated circuit dice from a silicon wafer, said method comprising the steps of:
setting a wafer cutting tool to a first cutting angle, wherein the first cutting angle is at substantially 90 degrees from a zero degree reference;
cutting the entire silicon wafer with the wafer cutting tool at the first cutting angle;
setting the wafer cutting tool to a second cutting angle, wherein the second cutting angle is less than 90 degrees from the zero degree reference;
cutting the entire silicon wafer with the wafer cutting tool at the second cutting angle;
setting the wafer cutting tool to a third cutting angle, wherein the third cutting angle is greater than 90 degrees from the zero degree reference; and
cutting the entire silicon wafer with the wafer cutting tool at the third cutting angle;
wherein a plurality of integrated circuit dice are separated from the silicon wafer and each one of the plurality of integrated circuit dice have six sides with corners greater than 90 degrees.

2. The method according to claim 1, wherein the silicon wafer is mounted to a wafer mount with mounting tape for holding the silicon wafer during cutting thereof with the wafer cutting tool.

3. The method according to claim 1, wherein passivation of each of the plurality of integrated circuit dice remains sealed after the steps of cutting the silicon wafer.

4. The method according to claim 1, wherein the step of cutting the silicon wafer at the first cutting angle comprises the steps of
cutting a first side of each of the plurality of integrated circuit dice at the first cutting angle; and
cutting a second side of each of the plurality of integrated circuit dice at the first cutting angle.

5. The method according to claim 1, wherein the step of cutting the silicon wafer at the second cutting angle comprises the steps of:
cutting a third side of each of the plurality of integrated circuit dice at the second cutting angle; and
cutting a fourth side of each of the plurality of integrated circuit dice at the second cutting angle.

6. The method according to claim 1, wherein the step of cutting the silicon wafer at the third cutting angle comprises the steps of:
cutting a fifth side of each of the plurality of integrated circuit dice at the third cutting angle; and
cutting a sixth side of each of the plurality of integrated circuit dice at the third cutting

7. A method for separating a plurality of integrated circuit dice from a silicon wafer, said method comprising the steps of:
setting a wafer cutting tool to a first cutting angle, wherein the first cutting angle is at substantially 90 degrees from a zero degree reference;
cutting the entire silicon wafer with the wafer cutting tool at the first cutting angle;
setting the wafer cutting tool to a second cutting angle, wherein the second cutting angle is less than 90 degrees from the zero degree reference;
cutting the entire silicon wafer with the wafer cutting tool at the second cutting angle;
setting the wafer cutting tool to a third cutting angle, wherein the third cutting angle is greater than 90 degrees from the zero degree reference;
cutting the entire silicon water with the wafer cutting tool at the third cutting angle;
setting the wafer cutting tool to a fourth cutting angle, wherein the fourth cutting angle is at substantially the zero degree reference; and
cutting the entire silicon wafer with the wafer cutting tool at the fourth cutting angle;
wherein a plurality of integrated circuit dice are separated from the silicon wafer and each one of the plurality of integrated circuit dice have eight sides with corners greater than 90 degrees.

8. The method according to claim 7, wherein the silicon wafer is mounted to a wafer mount with mounting tape for holding the silicon wafer during cutting thereof with the wafer cutting tool.

9. The method according to claim 7, wherein passivation of each of the plurality of integrated circuit dice remains sealed after the steps of cutting the silicon wafer.

10. The method according to claim 7, wherein the step of cutting the silicon wafer at the first cutting angle comprises the steps of
cutting a first side of each of the plurality of integrated circuit dice at the first cutting angle; and
cutting a second side of each of the plurality of integrated circuit dice at the first cutting angle,

11. The method according to claim 7, wherein the step of cutting the silicon wafer at the second cutting angle comprises the steps of:
cutting a third side of each of the plurality of integrated circuit dice at the second cutting angle; and
cutting a fourth side of each of the plurality of integrated circuit dice at the second cutting angle.

12. The method according to claim 7, wherein the step of cutting the silicon wafer at the third cutting angle comprises the steps of:
cutting a fifth side of each of the plurality of integrated circuit dice at the third cutting angle; and
cutting a sixth side of each of the plurality of integrated circuit dice at the third cutting angle.

13. The method according to claim 7, wherein the step of cutting the silicon wafer at the fourth cutting angle comprises the steps of:
cutting a seventh side of each of the plurality of integrated circuit dice at the fourth cutting angle; and
cutting an eighth side of each of the plurality of integrated circuit dice at the fourth cutting angle.

14. The method according to claim 1, wherein said step of cutting the entire silicon wafer with the wafer cutting tool at the first, second and third cutting angle is performed multiple times at each respective angle such that parallel cuts through the silicon wafer at said first, second, and third cutting angles are performed, respectively,

15. The method according to claim 1, wherein the wafer cutting tool is a wafer cutting saw,

16. The method according to claim 1, wherein after cutting the wafer comprises sacrificial areas arranged between said integrated circuit dice.

17. The method according to claim 7, wherein said step of cutting the entire silicon wafer with the wafer cuffing tool at the first, second, third and fourth cutting angle is performed multiple times at each respective angle such that parallel cuts through the silicon wafer at said first, second, third and fourth cutting angles are performed, respectively,

18. The method according to claim 7, wherein the wafer cutting tool is a wafer cutting saw.

19. The method according to claim 7, wherein after cutting the wafer comprises sacrificial areas arranged between said integrated circuit dice.

20. A method for separating a plurality of integrated circuit dice from a silicon wafer, said method comprising the steps of:
setting a wafer cutting saw to a first cutting angle to cut along a first cutting line, wherein the first cutting angle is at substantially 90 degrees from a zero degree reference;
performing a continuous cut through the silicon wafer along the first cutting line with the wafer cutting saw;
setting the wafer cutting saw to a second cutting angle to cut along a second cutting line, wherein the second cutting angle is less than 90 degrees from the zero degree reference;
performing a continuous cut through the silicon wafer along the second cutting line with the wafer cutting tool;
setting the wafer cutting tool to a third cutting angle to cut along a third cutting line, wherein the third cutting angle is greater than 90 degrees from the zero degree reference; and
performing a continuous cut through the silicon wafer along the third cutting line with the wafer cutting tool;
wherein a plurality of integrated circuit dice are separated from the silicon wafer and each one of the plurality of integrated circuit dice have six sides with corners greater than 90 degrees.
